(19) United States
(12) Patent Application Publication
(10) Pub. No.: US 2013/0182734 A1
(43) Pub. Date: Jul. 18, 2013

(54) LASER DIODE AND METHOD OF MANUFACTURING LASER DIODE

(71) Applicants: Sumitomo Electric Industries, Ltd., Osaka-shi (JP); Sony Corporation, Tokyo (JP)

(72) Inventors: Tatsushi Hamaguchi, Tokyo (JP); Shimpei Takagi, Osaka (JP)

(73) Assignees: SONY CORPORATION, Tokyo (JP); SUMITOMO ELECTRIC INDUSTRIES, LTD., Osaka (JP)

(21) Appl. No.: 13/735,746

(22) Filed: Jan. 7, 2013

(30) Foreign Application Priority Data
Jan. 13, 2012 (JP) 2012-005367

(51) Int. Cl. H01S 5/30

(52) U.S. Cl. CPC H01S 5/3013
USPC 372/44.011; 438/46

(57) ABSTRACT

A laser diode includes: a semiconductor base made of a hexagonal Group III nitride semiconductor and having a semi-polar plane oriented along a {2, 0, −2, 1} direction; an epitaxial layer including a light-emitting layer forming an optical waveguide of laser light, and formed on the semi-polar plane of the semiconductor base, the epitaxial layer allowing a propagation direction of the laser light to be tilted, in an optical waveguide plane, at an angle ranging from about 8° to about 12° or about 18° to about 29° both inclusive with respect to a direction of projection of a c axis onto the optical waveguide plane, the optical waveguide plane including the propagation direction of the laser light and being parallel to the semi-polar plane; two resonator facets; a first electrode; and a second electrode.

### CROSS REFERENCES TO RELATED APPLICATIONS

The present application claims priority to Japanese Priority Patent Application JP 2012-005367 filed in the Japan Patent Office on Jan. 13, 2012, the entire content of which is hereby incorporated by reference.

### BACKGROUND

The present disclosure relates to a laser diode and a method of manufacturing the same, and more specifically, the disclosure relates to a hexagonal Group III nitride laser diode and a method of manufacturing the same.

Laser diodes are presently utilized in various fields, and in particular, the laser diodes are indispensable optical devices in the field of image display units, for example, televisions and projectors. In the application of laser diodes to this field, laser diodes emitting light of respective light's primary colors, i.e., red, green, and blue are necessary. Red and blue laser diodes have been already practically used, and recently, green laser diodes (with a wavelength of about 500 nm to 560 nm both inclusive) have been actively developed (for example, refer to Takashi Kyono, et al., “Development I of world's first green laser diode on novel GaN substrate”, January 2010, SEI Technical Review, Vol. 176, pp. 88-92, and Masahiro Adachi, et al., “Development II of world's first green laser diode on novel GaN substrate”, January 2010, SEI Technical Review, Vol. 176, pp. 93-96).

In Takashi Kyono, et al., “Development I of world's first green laser diode on novel GaN substrate”, January 2010, SEI Technical Review, Vol. 176, pp. 88-92, and Masahiro Adachi, et al., “Development II of world's first green laser diode on novel GaN substrate”, January 2010, SEI Technical Review, Vol. 176, pp. 93-96, there is proposed a hexagonal Group III nitride laser diode in which an n-type cladding layer, a light-emitting layer including an active layer made of InGaN, and a p-type cladding layer are formed in this order on a {2, 0, −2, 1} semi-polar plane of an n-type GaN substrate. In the laser diode fabricated through laminating (epitaxially growing) various laser component films on the semi-polar plane of such a semiconductor substrate, a facet thereof orthogonal to a propagation direction (a waveguide direction) of laser light is used as a reflective plane (hereinafter referred to as “resonator facet”). It is to be noted that, in this specification, plane orientation of a hexagonal crystal is represented by {h, k, l, m}, where h, k, l, and m are plane indices (Miller indices).

Moreover, a laser diode using a semiconductor substrate with a semi-polar plane (hereinafter referred to as “semi-polar substrate”), optimization of the propagation direction of laser light has been studied (for example, refer to Japanese Unexamined Patent Application Publication (Published Japanese Translation of PCT Application) No. 2010-518626). Japanese Unexamined Patent Application Publication No. 2010-518626 discloses a technique of orienting a light propagation axis substantially perpendicular to a light polarization direction or a crystallographic orientation in a semi-polar Group III nitride diode laser. More specifically, in Japanese Unexamined Patent Application Publication No. 2010-518626, the light propagation axis is oriented substantially along a “c” axis of the semi-polar Group III nitride diode laser to maximize optical gain.

### SUMMARY

As described above, a suitable propagation direction of laser light in a laser diode using a semi-polar substrate has been studied. However, in this technical field, it is desired to develop a technique of further optimizing the propagation direction of laser light in the laser diode using the semi-polar substrate to further improve laser characteristics.

It is desirable to provide a laser diode with use of a semi-polar substrate achieving superior laser characteristics through further optimizing a propagation direction of laser light, and a method of manufacturing the same.

According to an embodiment of the disclosure, there is provided a laser diode including: a semiconductor base made of a hexagonal Group III nitride semiconductor and having a semi-polar plane oriented along a {2, 0, −2, 1} direction; an epitaxial layer including a light-emitting layer forming an optical waveguide of laser light, and formed on the semi-polar plane of the semiconductor base, the epitaxial layer allowing a propagation direction of the laser light to be tilted, in an optical waveguide plane, at an angle ranging from about 8° to about 12° or about 18° to about 29° both inclusive with respect to a direction of projection of a c axis onto the optical waveguide plane, the optical waveguide plane including the propagation direction of the laser light and being parallel to the semi-polar plane; two resonator facets disposed at both ends of the optical waveguide of the laser light; a first electrode formed on the epitaxial layer; and a second electrode formed on a plane opposite to the semi-polar plane where the epitaxial layer is formed of the semiconductor base.

As used herein, the wording “a semi-polar plane oriented along a {2, 0, −2, 1} direction” encompasses not only “a semi-polar plane oriented exactly along the {2, 0, −2, 1} direction” but also “a semi-polar plane oriented along a direction slightly tilted from the {2, 0, −2, 1} direction”.

According to an embodiment of the disclosure, there is provided a method of manufacturing a laser diode, the method including: forming an epitaxial layer on a semi-polar plane oriented along a {2, 0, −2, 1} direction of a semiconductor base made of a hexagonal Group III nitride semiconductor, the epitaxial layer including a light-emitting layer forming an optical waveguide of laser light, and allowing a propagation direction of the laser light to be tilted, in an optical waveguide plane, at an angle ranging from about 8° to about 12° or about 18° to about 29° both inclusive with respect to a direction of projection of a c axis onto the optical waveguide plane, the optical waveguide plane including the propagation direction of the laser light and being parallel to the semi-polar plane; forming a first electrode and a second electrode on the epitaxial layer and a plane opposite to the semi-polar plane of the semiconductor base, respectively; and forming two resonator facets at both ends of the optical waveguide of the laser light.

As described above, the laser diode according to the embodiment of the disclosure is a laser diode using a semiconductor base made of the hexagonal Group III nitride semiconductor and having a semi-polar plane oriented along the {2, 0, −2, 1} direction. Further, in the embodiment of the disclosure, the propagation direction of the laser light in the optical waveguide plane including the propagation direction of the laser light and being parallel to the semi-polar plane is determined at a direction tilted at an angle ranging from about 8° to about 12° or from about 18° to about 29° both inclusive with respect to the direction of projection of the c axis onto the optical waveguide plane. In the embodiment of the disclosure, the propagation direction of the laser light is determined at the above-described direction, thereby making it possible to improve orthogonality between the propagation direction of the laser light and the resonator facet, and to further improve laser characteristics.

Additional features and advantages are described herein, and will be apparent from the following Detailed Description and the figures.

### BRIEF DESCRIPTION OF THE FIGURES

The accompanying drawings are included to provide a further understanding of the technology, and are incorporated in and constitute a part of this specification. The drawings illustrate embodiments and, together with the specification, serve to explain the principles of the technology.

FIG. 1 is a schematic perspective view of a laser diode according to an embodiment of the disclosure.

FIGS. 2A and 2B are diagrams illustrating a crystal structure of GaN.

FIG. 3 is a diagram illustrating an example of a semi-polar plane in the crystal structure of GaN.

FIG. 4 is a schematic sectional view of the laser diode according to the embodiment of the disclosure.

FIG. 5 is a flow chart illustrating steps of a method of manufacturing the laser diode according to the embodiment of the disclosure.

FIG. 6 is a plot illustrating a relationship between a tilt angle (a deviation amount) from an ideal facet of a resonator facet and a lasing threshold current Ith.

FIG. 7 is a schematic configuration diagram of a numerical analysis model of the laser diode.

FIG. 8 is a table illustrating numerical analysis results.

FIG. 9 is a table illustrating numerical analysis results.

FIG. 10 is a plot illustrating a relationship between a tilt angle (a horizontal deviation amount) from an ideal value of an extending direction of a stripe section with respect to the resonator facet in a plane where the stripe section was formed and the lasing threshold current Ith.

### DETAILED DESCRIPTION

A preferred embodiment of the disclosure will be described in detail below referring to the accompanying drawings in the following order. It is to be noted that the present disclosure is not limited to the following examples.
1. Configuration of Laser Diode
2. Method of Manufacturing Laser Diode
3. Configuration of Stripe Section

(1. Configuration of Laser Diode)

[Entire Configuration of Laser Diode]

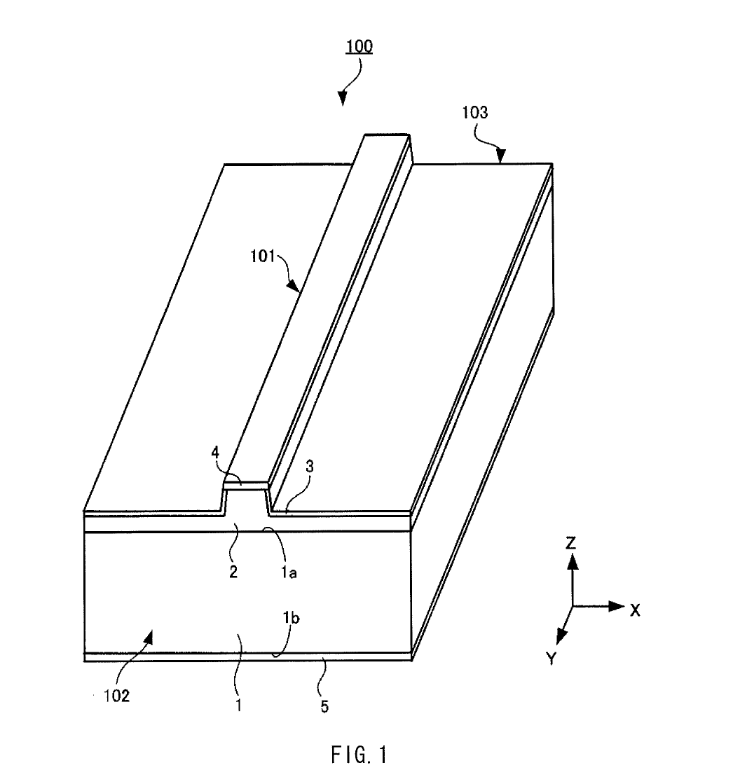

FIG. 1 illustrates a schematic outline view of a laser diode according to an embodiment of the disclosure. It is to be noted that, in an example illustrated in FIG. 1, a ridge (refractive index-guided) laser diode 100 is illustrated; however, the present disclosure is not limited thereto. For example, technology which will be described below of the disclosure is applicable to a gain-guided laser diode.

The laser diode 100 includes a semiconductor base 1, an epitaxial layer 2, an insulating layer 3, a first electrode 4, and a second electrode 5.

In the laser diode 100 according to the embodiment, one surface la (a top surface in FIG. 1) of the semiconductor base 1 serves as a semi-polar plane, and the epitaxial layer 2, the insulating layer 3, and the first electrode 4 are formed in this order on the semi-polar plane la. Moreover, the second electrode 5 is formed on a surface 1b (a bottom surface in FIG. 1: hereinafter referred to as “back surface 1b”) opposite to the semi-polar plane 1a of the semiconductor base 1. It is to be noted that, in the case where a semi-polar plane oriented around a {2, 0, −2, 1} direction is used as the semi-polar plane 1a of the semiconductor base 1, for example, green light with a wavelength around 500 nm is capable of being oscillated.

Moreover, as illustrated in FIG. 1, the laser diode 100 has a substantially rectangular parallelepiped shape, and a stripe section 101 with a ridge configuration extending along a predetermined direction (in a Y direction in FIG. 1) is formed on a surface facing the first electrode 4 of the laser diode 100. The stripe section 101 is formed to extend from one side surface 102 which will be described later of the laser diode 100 to the other side surface 103 thereof An extending direction of the stripe section 101 serves as a propagation direction (a waveguide direction) of laser light, and a region corresponding to the stripe section 101 of the epitaxial layer 2 serves as an optical waveguide.

In the embodiment, the propagation direction of laser light is determined to be tilted, in an optical waveguide plane including the propagation direction of laser light and being parallel to the semi-polar plane la, at an angle ranging from about 8° to about 12° or about from 18° to about 29° both inclusive with respect to a direction of projection of a “c” axis onto the optical waveguide plane. More specifically, an extending direction of the stripe section 101 is determined to be tilted, on a plane where the stripe section 101 is formed, at an angle ranging from about 8° to about 12° or from about 18° to about 29° both inclusive with respect to a direction of projection of the c axis onto the plane where the stripe section 101 is formed (hereinafter referred to as “c-axis projection direction”). It is to be noted that one reason why the extending direction of the stripe section 101 is tilted at an angle within the above-described angle range with respect to the c-axis projection direction will be described in detail later. It is to be noted that a width of the stripe section 101 is several micrometers or less, and an extending length (a resonator length) of the stripe section 101 is around several hundreds of micrometers.

Moreover, the laser diode 100 has four side surfaces (facets), and two side surfaces 102 and 103 (cut surfaces) substantially perpendicular to the extending direction of the stripe section 101 (the Y direction in FIG. 1) of the four side surfaces function as reflection planes of a laser resonator. In other words, the two side surfaces 102 and 103 are resonator facets, and a laser resonator is configured of the two resonator facets 102 and 103 and an optical waveguide region corresponding to the stripe section 101 of the epitaxial layer 2. It is to be noted that, as will be described later, since the laser diode 100 is fabricated through cutting a substrate member (hereinafter referred to as “production substrate”) in which a plurality of laser diodes 100 are two-dimensionally formed and arranged into chips, these four side surfaces are cut surfaces formed during a process of cutting the production substrate.

It is to be noted that, in the laser diode 100 according to the embodiment, a dielectric multilayer film such as a SiO₂/TiO₂ film may be formed on one or both of the two resonator facets 102 and 103 (facet coating). Reflectivity of the resonator facet is adjustable through performing the facet coating.

[Configurations of Respective Components]

Configurations of respective components of the laser diode 100 according to the embodiment will be described in more detail below.

(1) Semiconductor Base

The semiconductor base 1 is made of, for example, a hexagonal Group III nitride semiconductor such as GaN, MN, AlGaN, InGaN, or InAlGaN. Moreover, as the semiconductor base 1, a substrate of which conductivity of carriers is n-type may be used. In the embodiment, as described above, one surface where the epitaxial layer 2, the insulating layer 3, and the first electrode 4 are formed of the semiconductor base 1 configures the semi-polar plane 1a.

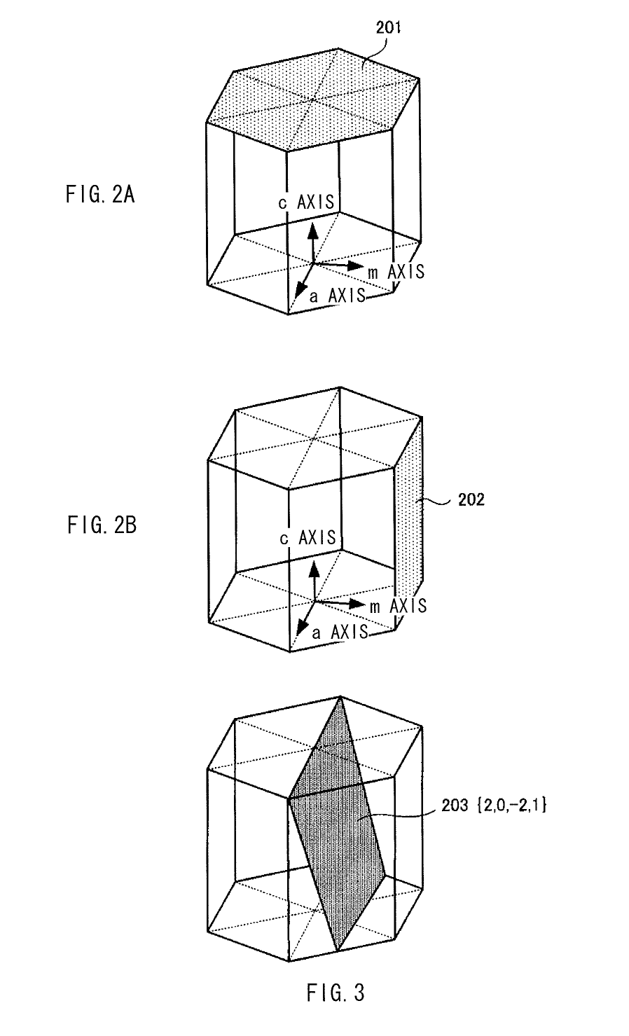

FIGS. 2A, 2B, and 3 illustrate a crystal structure of GaN. As illustrated in FIGS. 2A and 2B, GaN has a crystal structure called “hexagonal crystal”, and a piezoelectric field generated in the light-emitting layer which will be described later in the epitaxial layer 2 is generated along the c axis; therefore, a c-plane 201 (a {0, 0, 0, 1} plane) orthogonal to the c axis has polarity, and is called “polar plane”. On the other hand, since an m-plane 202 (a {1, 0, −1, 0} plane) orthogonal to an m axis is parallel to the c axis, the m-plane 202 is non-polar, and is called “non-polar plane”. On the contrary, a plane along an axis direction, as a normal direction, tilted at a predetermined angle with respect to the c axis toward the m axis, for example, a plane (a {2, 0, −2, 1} plane 203) along an axis direction, as a normal direction, tilted at 75° with respect to the c axis toward the m axis in an example illustrated in FIG. 3 is an intermediate plane between the c-plane and the m-plane, and is called “semi-polar plane”.

It is to be noted that, in the embodiment, a plane oriented around the {2, 0, −2, 1} direction is used as the semi-polar plane la. More specifically, a {2, 0, −2, 1} crystal plane and a crystal plane tilted slightly (for example, at about ±4°) with respect to the crystal plane are used as the semi-polar planes la. In the case where the semi-polar plane 1a oriented along such a direction is used and the extending direction of the stripe section 101 is tilted at an angle ranging from about 8° to about 12° or from about 18° to about 29° both inclusive with respect to the c-axis projection direction, as will be described later, the resonator facets 102 and 103 having favorable orthogonality are able to be formed.

Moreover, a thickness of the semiconductor base 1 may be determined to be about 400 μm or less, for example. In this thickness range, the resonator facets 102 and 103 (cut surfaces) with high quality (favorable flatness and favorable orthogonality) are obtainable in the process of cutting the production substrate configured of the laser diodes. In particular, when the semiconductor base 1 has a thickness ranging from about 50 μm to 100 μm both inclusive, the resonator facets 102 and 103 with higher quality are able to be formed.

(2) Epitaxial Layer, Insulating Layer, First Electrode, and Second Electrode

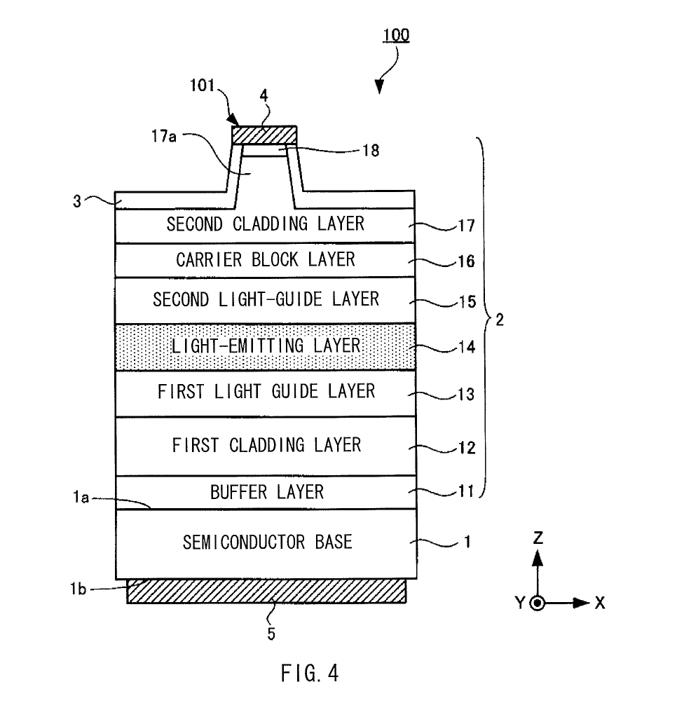

Next, the configurations of the epitaxial layer 2, the insulating layer 3, the first electrode 4, and the second electrode 5 of the laser diode 100 according to the embodiment will be described below referring to FIG. 4. FIG. 4 is a schematic sectional view in a thickness direction (a Z direction in the drawing) of the laser diode 100. It is to be noted that FIG. 4 illustrates a section orthogonal to the extending direction of the stripe section 101 (a Y direction in the drawing).

In the embodiment, the epitaxial layer 2 includes a buffer layer 11, a first cladding layer 12, a first light guide layer 13, a light-emitting layer 14 (an active layer), a second light guide layer 15, a carrier block layer 16, a second cladding layer 17, and a contact layer 18. The buffer layer 11, the first cladding layer 12, the first light guide layer 13, the light-emitting layer 14, the second light guide layer 15, the carrier block layer 16, the second cladding layer 17, and the contact layer 18 are laminated in this order on the semi-polar plane 1a of the semiconductor base 1. It is to be noted that an example in which the semiconductor base 1 is configured of an n-type GaN semi-polar substrate will be described here.

The buffer layer 11 may be configured of, for example, a gallium nitride-based semiconductor layer such as an n-type GaN layer. The first cladding layer 12 may be configured of, for example, a gallium nitride-based semiconductor layer such as an n-type AlGaN layer or an n-type InAlGaN layer. Further, the first light guide layer 13 may be configured of, for example, a gallium nitride-based semiconductor layer such as an n-type GaN layer or an n-type InGaN layer.

The light-emitting layer 14 is configured of, for example, a well layer (not illustrated) made of a gallium nitride-based semiconductor such as InGaN or InAlGaN and a barrier layer (not illustrated) made of a gallium nitride-based semiconductor such as GaN, InGaN, or InAlGaN. In the embodiment, the light-emitting layer 14 may have, for example, a multiple quantum well structure in which a plurality of well layers and a plurality of barrier layers are alternately laminated. It is to be noted that the light-emitting layer 14 serves as a light emission region of the epitaxial layer 2, and emits, for example, light with a wavelength ranging from about 480 nm to 550 nm both inclusive.

The second light guide layer 15 may be configured of a gallium nitride-based semiconductor layer of which conductivity of carriers is p-type, for example, a gallium nitride-based semiconductor layer such as a p-type GaN layer or a p-type InGaN layer. The carrier block layer 16 (an electron block layer) may be configured of, for example, a p-type AlGaN layer.

The second cladding layer 17 may be configured of a gallium nitride-based semiconductor layer such as a p-type AlGaN layer or a p-type InAlGaN layer. It is to be noted that the laser diode 100 according to the embodiment is a ridge laser diode; therefore, a region other than a region corresponding to the stripe section 101 of a surface facing the first electrode 4 of the second cladding layer 17 is carved by etching or the like. Accordingly, a ridge section 17a is formed in the region corresponding to the stripe section 101 of the surface facing the first electrode 4 of the second cladding layer 17. It is to be noted that, as with the stripe section 101, the ridge section 17a is formed to extend along a direction substantially orthogonal to each resonator facet, and is formed to extend from one resonator facet 102 to the other resonator facet 103.

The contact layer 18 may be configured of, for example, a p-type GaN layer. Moreover, the contact layer 18 is formed on the ridge section 17a of the second cladding layer 17.

The insulating layer 3 is configured of, for example, an insulating film such as a SiO₂ film. As illustrated in FIG. 4, the insulating layer 3 is formed on a region other than the ridge section 17a of the second cladding layer 17 and side surfaces of the ridge section 17a and the contact layer 18.

The first electrode 4 (a p-side electrode) may be configured of a conductive film such as a Pd film. Moreover, the first electrode 4 is formed on the contact layer 18 and a facet facing the contact layer 18 of the insulating layer 3. It is to be noted that, in the laser diode 100 according to the embodiment, an electrode film for a pad electrode may be disposed to cover the insulating layer 3 and the first electrode 4.

The second electrode 5 (an n-side electrode) may be configured of, for example, a conductive film such as an Al film. Moreover, the second electrode 5 is formed on the back surface 1b of the semiconductor base 1.

(2. Method of Manufacturing Laser Diode)

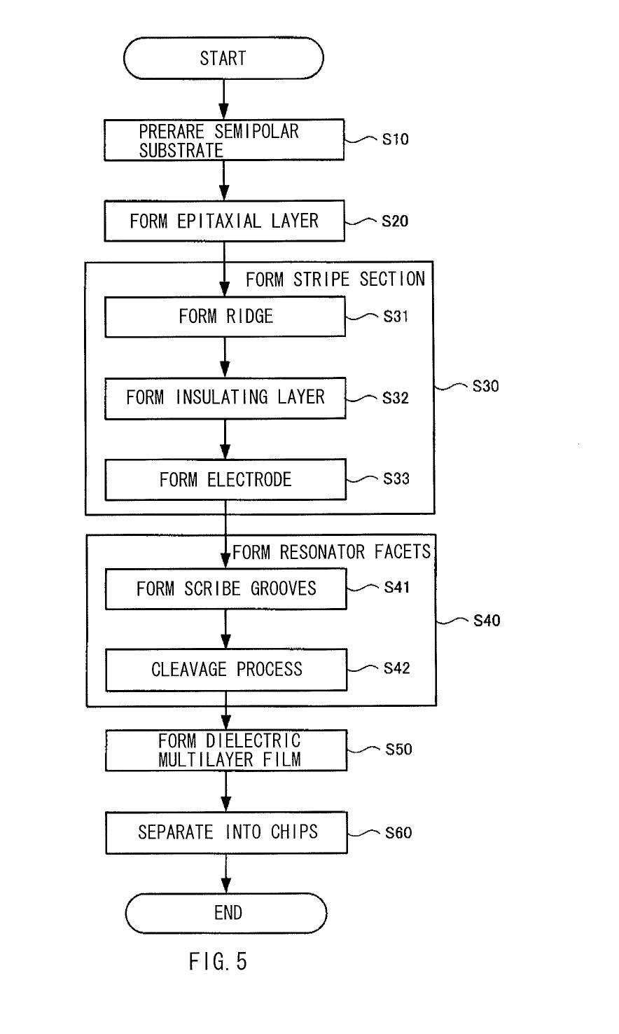

Next, a method of manufacturing the laser diode 100 according to the embodiment will be described in detail below referring to FIG. 5. FIG. 5 is a flow chart illustrating steps of the method of manufacturing the laser diode 100. Moreover, in the embodiment, an example in which a dielectric multilayer film is formed on each resonator facet of the laser diode 100 (facet coating) will be described.

First, a semi-polar substrate made of a hexagonal Group III nitride semiconductor on which a plurality of laser diodes 100 are to be two-dimensionally formed and arranged is prepared (step S10). Then, thermal cleaning is performed on the prepared semi-polar substrate.

Next, respective semiconductor films are epitaxially grown in predetermined order on a semi-polar plane of the semi-polar substrate by, for example, an OMVPE (organometallic metal vapor phase epitaxy) method to form semiconductor films configuring the epitaxial layer 2 (step S20). More specifically, respective semiconductor films configuring the buffer layer 11, the first cladding layer 12, the first light guide layer 13, the light-emitting layer 14, the second light guide layer 15, the carrier block layer 16, the second cladding layer 17, and the contact layer 18 are epitaxially grown in this order on the semi-polar plane.

Next, the stripe section 101 of each laser diode 100 is formed on a surface where the semiconductor films are disposed of the semi-polar substrate (step S30). At this time, the stripe section 101 of each laser diode 100 is so formed on the surface where the semiconductor films are disposed as to allow the extending direction of the stripe section 101 of each laser diode 100 to be tilted at an angle ranging from about 8° to about 12° or from about 18° to about 29° both inclusive with respect to the c-axis projection direction. More specifically, the stripe section 101 is formed as follows.

First, a mask is formed on a region where the stripe section 101 is to be formed of a surface region where the semiconductor film configuring the contact layer is disposed of the semi-polar substrate. At this time, the mask is so formed as to allow an extending direction of the mask in a plane where the mask is to be formed to be tilted at an angle ranging from about 8° to about 12° or from about 18° to about 29° both inclusive with respect to the c-axis projection direction. Then, a region other than the region where the mask is formed is etched to form a ridge on a surface facing the contact layer 18 of each laser diode 100 (step S31).

It is to be noted that, at this time, the region other than the region where the stripe section 101 is to be formed is carved from a surface of the contact layer 18 to a predetermined depth of the second cladding layer 17 to form the ridge in the region where the stripe section 101 is to be formed. The ridge extending in a direction tilted at a predetermined angle ranging from about 8° to about 12° or from about 18° to about 29° both inclusive with respect to the c-axis projection direction in a plane of the surface facing the contact layer 18 of each laser diode 100 is thus formed through this process. Moreover, at this time, the ridge is so continuously formed as to cross a border between regions where two laser diodes 100 adjacent to each other in the extending direction of the stripe section 101 are to be formed.

Next, after the mask on the ridge is removed, an insulating film configuring the insulating layer 3 is formed on a surface on the ridge side of the semi-polar substrate with use of, for example, an evaporation method or a sputtering method (step S32). It is to be noted that the mask on the ridge may be removed after the insulating film is formed. Moreover, in the case where the mask is formed of, for example, metal or the like, the mask may be used as a part of the first electrode 4; therefore, the mask may not be removed.

Next, electrode films configuring the first electrode 4 and the second electrode 5 are formed on a substrate member fabricated through forming various semiconductor films and the insulating film on the semi-polar substrate in the above-described manner (step S33).

More specifically, the electrode film (a first electrode film) configuring the first electrode 4 is formed by the following manner. First, the insulating film on each ridge is removed with use of photolithography to expose a surface of the contact layer 18. Next, the electrode film configuring the first electrode 4 is formed on each exposed contact layer 18 with use of, for example, the evaporation method or the sputtering method.

On the other hand, the electrode film (a second electrode film) configuring the second electrode 5 is formed in the following manner. First, the back surface of the semi-polar substrate is polished to allow the semi-polar substrate to have a desired thickness. Next, the electrode film configuring the second electrode 5 is formed on the entire back surface of the semi-polar substrate with use of, for example, the evaporation method or the sputtering method.

In the embodiment, the stripe section 101 extending along a direction tilted at an angle ranging from about 8° to about 12° or from about 18° to about 29° both inclusive with respect to the c-axis projection direction in the plane of the surface facing the contact layer 18 of each laser diode 100 is formed by the above-described steps S31 to S33. Moreover, in the embodiment, the production substrate fabricated through two-dimensionally forming and arranging a plurality of laser diodes 100 is formed by the above-described steps S10 to S30 (S31 to S33).

Next, a process from step S40 onward, that is, a process of cutting the production substrate into the laser diodes 100 (a cutting process) will be described in order. It is to be noted that in the process of cutting the production substrate into the laser diodes 100, a technique similar to a technique in related art may be used, and a technique using a laser scribing unit (not illustrated) will be described below.

First, each resonator facet of each laser diode 100 is formed (step S40). More specifically, the production substrate is placed on the laser scribing unit, and a scribe groove is formed through applying a laser beam to a part of a scribe line along the resonator facets of the plurality of laser diodes 100 two-dimensionally arranged in the production substrate (step S41). At this time, the scribe groove is formed on and along a scribe line of an edge region of the production substrate.

Next, a breaking unit called “blade” (not illustrated) is pressed onto a region facing a region where the scribe groove is formed of the back surface of the production substrate to cut (cleave) the production substrate along the scribe line (step S42). Then, this cutting process is repeatedly performed on each of scribe lines along the resonator facets of the laser diodes 100 to cut the production substrate into a plurality of substrate members. It is to be noted that an example in which the resonator facets are formed by cutting (cleaving) process is described in this embodiment; however, the disclosure is not limited thereto, and the resonator facets may be formed by, for example, dry etching or the like.

It is to be noted that, in the embodiment, as described above, the extending direction of the stripe section 101 of each laser diode 100 is equal to a direction tilted at a predetermined angle ranging from about 8° to about 12° or from about 18° to about 29° both inclusive with respect to the c-axis projection direction. In this case, as will be described later, an angle between a crystal plane which is possible to be exposed to the resonator facet formed in the above-described step S40 and a plane (the semi-polar plane 1a) where the stripe section 101 is formed is allowed to more closely approach an ideal value (90°). More specifically, for example, a difference between the angle between the crystal plane which is possible to be exposed to the resonator facet and the plane (the semi-polar plane 1a) where the stripe section 101 is formed and the ideal value (90°) is able to be, for example, about 3° or less; therefore, orthogonality between both the angles is further improved.

Next, the dielectric multilayer film is formed on a cut surface (the resonator facet) of each of the substrate members separated in the above-described step S40 (step S50). Then, each substrate member is cut along an extending direction of a scribe line orthogonal to the scribe line along the resonator facet of the laser diode 100 of each substrate member to be separated into a plurality of chips, that is, laser diodes 100 (step S60). In the embodiment, the laser diode 100 is fabricated in the above-described manner.

(3. Configuration of Stripe Section)

Next, the configuration of the stripe section 101 in the laser diode 100 according to the embodiment will be described in more detail below. In the laser diode 100 according to the embodiment, as described above, the extending direction of the stripe section 101 is determined at a direction tilted at an angle ranging from about 8° to about 12° or from about 18° to about 29° both inclusive with respect to the c-axis projection direction in a plane where the stripe section 101 is formed. Therefore, orthogonality between a propagation direction of laser light (the extending direction of the stripe section 101) and the resonator facet is improvable, and favorable laser characteristics are obtainable. One reason for this will be described below.

(1) Suitable Range of Tilt Angle of Resonator Facet

In a laser diode in related art, a resonator facet is formed orthogonal to a waveguide for laser light (a stripe section). Moreover, a multilayer film (a dielectric multilayer film) made of, for example, a dielectric is formed on the resonator facet to improve various laser characteristics including, for example, the lasing threshold current Ith. More specifically, when the dielectric multilayer film is formed on the resonator facet, reflectivity of the resonator facet is further improved than that in the case where the dielectric multilayer film is not formed on the resonator facet (without coating), and various laser characteristics including, for example, the lasing threshold current Ith are improved accordingly.

At this time, to improve the laser characteristics, in particular, reflectivity of a rear facet serving as a resonator facet not extracting laser light is typically made higher than that in the case where the resonator facet is not coated. It is to be noted that reflectivity of a front facet serving as a resonator facet extracting laser light may be also made high in terms of laser characteristics and design flexibility, though the reflectivity of the front facet depends on various conditions including, for example, a laser resonator length and crystallinity of a used semiconductor. In other words, in the laser diode, practically, the resonator facet having higher reflectivity than the resonator facet without coating may be formed to allow more light to be returned to an inside of the laser resonator, compared to the resonator facet without coating.

The above-described qualitative configuration conditions of the resonator facets will be described more quantitatively with use of theoretical calculation. Reflectivity R of the resonator facet without coating is determined by R=(n₀−n₁)²/(n₀+n₁)², where n₀ is a refractive index of a medium (typically, air), and n₁ is a refractive index of a semiconductor. It is to be noted that the reflectivity R represented by the above-described expression is reflectivity when laser light enters the resonator facet perpendicular thereto.

For example, a refractive index of an InAlGaN-based nitride semiconductor falls in a range of about 2 to 3 both inclusive, depending on a wavelength of expected light or a semiconductor composition; therefore, in a laser diode using such a quaternary semiconductor, the reflectivity R of the resonator facet without coating falls in a range of about 10% to 25% both inclusive. Therefore, in an InAlGaN-based nitride laser diode, it is necessary to return 10% or more of light incident on the resonator facet to an inside of a laser resonator. Moreover, in the InAlGaN-based nitride laser diode, about 25% of light incident on the resonator facet is preferably returned to the laser diode, and larger than about 25% of the light is more preferably returned to the laser resonator.

However, when the orthogonality between the resonator facet and the extending direction of the stripe section (the propagation direction of laser light) is lost, a light reflection direction by the resonator facet does not coincide with the propagation direction of laser light; therefore, it is difficult to satisfy the above-described conditions (the percentage of returned light) in the resonator facet.

Therefore, when inventors of the present disclosure carried out an verification of a relationship between deviation from orthogonality between the resonator facet and the extending direction of the stripe section (the propagation direction of laser light) and the percentage of light returned to the laser resonator by theoretical calculation, the following finding was obtained. It is to be noted that this verification was carried out based on, for example, a typical nitride laser diode having a semiconductor with a refractive index n₁ of 2.5 and an emission angle in a vertical direction (the thickness direction of the semiconductor base) of 20°. Moreover, this verification was carried out based on the assumption that both a light intensity distribution emitted from the laser diode and a light intensity distribution in the laser diode are Gaussian distributions and spreads of the light intensity distributions were inversely proportional to a refractive index ratio. Further, in this verification, reflectivity of the resonator facet when an angle between the resonator facet and a plane where a stripe section was formed was 90° (an ideal value) was 100%.

As a result, it was found out that, when the angle between the resonator facet and the plane where the stripe section was formed was tilted by about 3° with respect to 90°, the percentage of light returned to the inside of the resonator was reduced to about 25%. Moreover, it was found out that when the angle between the resonator facet and the plane where the stripe section was formed was tilted by about 6° with respect to 90°, the percentage of light returned to the inside of the laser resonator was reduced to about 10%.

It was found out from the above verification results that, when a deviation amount (a tilt angle) from an ideal value of the angle between the resonator facet and the plane where the stripe section was formed was about 6° or less, and more preferably about 3° or less, the above-described qualitative configuration conditions of the resonator facet were satisfied. In other words, it was found out that the ideal value of the angle between the resonator facet and the plane where the stripe section was formed was preferably 90°; however, even if the angle was deviated from the ideal value, sufficiently favorable laser characteristics were obtained as long as the deviation amount from the ideal value was about 6° or less, and more preferably about 3° or less. It is to be noted that the resonator facet when the angle between the resonator facet and the plane where the stripe section is formed is 90° (the ideal value) is referred to as “ideal facet” in the following.

In the InAlGaN-based nitride laser diode fabricated with use of a semi-polar substrate having a {2, 0, −2, 1} plane, a relationship between a tilt angle (a deviation amount) from the ideal facet of the resonator facet and the lasing threshold current Ith was actually determined. It is to be noted that, in the InAlGaN-based nitride laser diode fabricated here, a dielectric multilayer film was formed on each of a front facet and a rear facet, and the reflectivity of the front facet was adjusted to 55% and the reflectivity of the rear facet was adjusted to 95%.

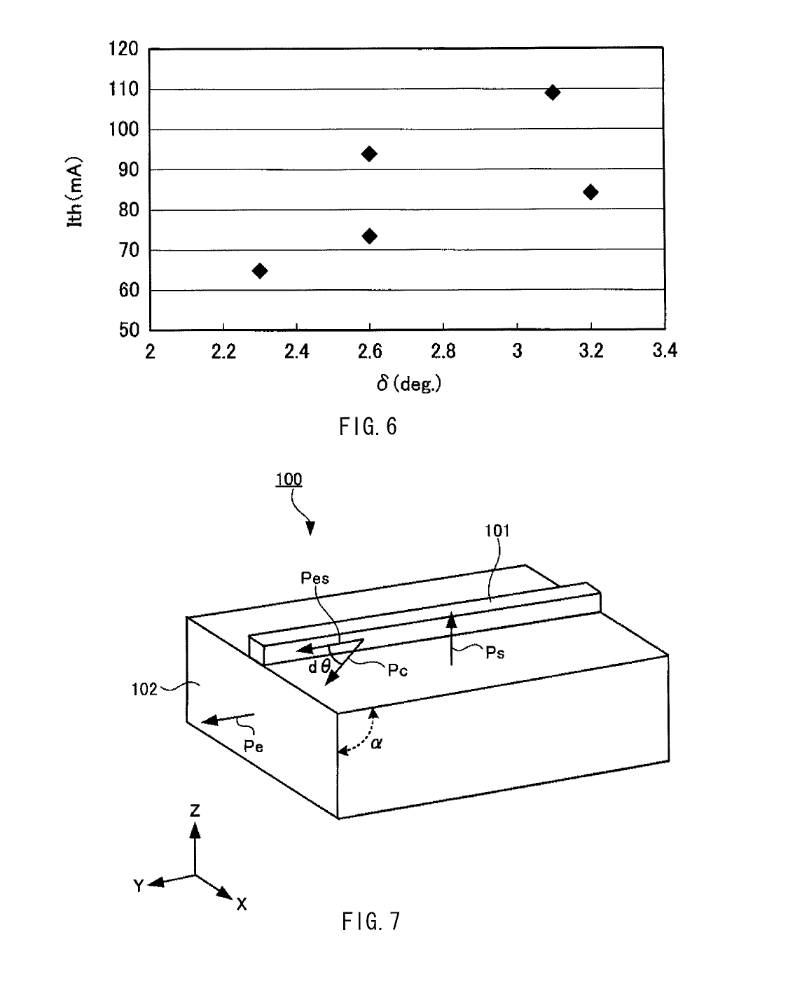

FIG. 6 illustrates measurement results. It is to be noted that a horizontal axis in characteristics illustrated in FIG. 6 represents an tilt angle (a deviation amount) from the ideal value (90°) of the angle of the resonator facet with respect to the plane where the stripe section is formed, that is, an tilt angle with respect to the ideal facet of the resonator facet, and a vertical axis represents the lasing threshold current Ith. As illustrated in FIG. 6, the lasing threshold current Ith was increased with an increase in the tilt angle of the resonator facet; however, when the tilt angle approached 3°, the lasing threshold current Ith was increased, and when the tilt angle exceeded 3°, the lasing threshold current Ith was further increased. It was also found out from this measurement results that, as in the above-described verification results by theoretical calculation, the tilt angle with respect to the ideal facet of the resonator facet was more preferably about 3° or less to obtain favorable laser characteristics.

(2) Suitable Extending Direction of Stripe Section

Next, a preferable extending direction of the stripe section in a hexagonal Group III nitride diode using a semiconductor base (hereinafter referred to as “semi-polar base”) having a semi-polar plane oriented along the {2, 0, −2, 1} direction will be described below.

Typically, in the hexagonal group III nitride laser diode using the semi-polar base, the extending direction of the stripe section (the propagation direction of laser light) is determined to be oriented along a direction of projection of the c-axis onto the plane (the semi-polar plane) where the stripe section is formed. However, in this case, the resonator facet is not an easily cleavable plane such as a “c” plane, an “m” plane, or an “a” plane (refer to FIGS. 2A and 2B). Therefore, in this case, it is difficult to orient, at 90° (an ideal value), the angle between the plane where the stripe section is formed and the resonator facet, and it is difficult to determine the deviation amount (the tilt angle) from the ideal facet of the resonator facet to satisfy the above-described angle condition (about 6° or less, and preferably about 3° or less).

Therefore, whether or not the extending direction of the stripe section allowing the deviation amount from the ideal value of the angle between the plane where the stripe section was formed and the resonator facet to satisfy the above-described angle condition exists in the laser diode using the semi-polar base oriented along the {2, 0, −2, 1} direction was determined by numerical analysis.

FIG. 7 illustrates a schematic perspective view of an analysis model of the laser diode 100 used for the numerical analysis. It is to be noted that vector operation was used as a method of the numerical analysis.

More specifically, an angle α between a predetermined crystal plane (an {h, k, l, m} plane) and a semi-polar plane 1a (a {2, 0, −2, 1} plane) in the hexagonal crystal was determined by the following expression (1).

$$\begin{matrix}[ Mathematical Expression 1 ] & \\ α = arccos ( \frac{Pe \cdot Ps}{\vert Pe \vert \vert Ps \vert} ) & ( 1 )\end{matrix}$$

Moreover, a deviation amount dθ (a tilt angle) from the c-axis projection direction of the extending direction of the stripe section 101 when the predetermined crystal plane (the {h, k, l, m} plane) was considered as the resonator facet 102 was determined by the following expression (2).

$$\begin{matrix}[ Mathematical Expression 2 ] & \\ d θ = arccos ( \frac{Pes \cdot Ps}{\vert Pes \vert \vert Pc \vert} ) & ( 2 )\end{matrix}$$

It is to be noted that a vector “Pe” in the above-described expression (1) is a vector representing plane orientation of the crystal plane (the {h, k, l, m} plane: the resonator facet), and a vector “Ps” is a vector representing plane orientation of the semi-polar plane la. Moreover, a vector “Pc” in the above-described expression (2) is a vector representing the c-axis projection direction as a reference of the extending direction of the stripe section 101. However, the above-described vectors are vectors when plane indices (h, k, l, and m) of the hexagonal crystal are converted into rectangular coordinates, and the above-described vectors are represented by the following expression (3).

$$\begin{matrix}[ Mathematical Expression 3 ] & \\ Pe = ( \begin{matrix}x \\ y \\ z\end{matrix} ) = ( \begin{matrix}1 & 0 & 0 \\ 1 / \sqrt{3} & 2 / \sqrt{3} & 0 \\ 0 & 0 & a / c\end{matrix} ) ( \begin{matrix}h \\ k \\ m\end{matrix} ) , \\ Ps = ( \begin{matrix}2.00 \\ 1.15 \\ 0.61\end{matrix} ) , \\ Pc = ( \begin{matrix}- 1.73 \\ - 1.00 \\ 7.53\end{matrix} ) & ( 3 )\end{matrix}$$

Moreover, “c” in the above-described expression (3) represents a lattice constant along the c-axis direction of the hexagonal crystal, and “a” represents a lattice constant along an a-axis direction of the hexagonal crystal. Moreover, a vector “Pes” in the above-described expression (2) represents an in-plane direction component of the semi-polar plane 1a of the vector “Pe”, and is represented by the following expression (4).

$$\begin{matrix}[ Mathematical Expression 4 ] & \\ Pes = Pe - \frac{Pe \cdot Ps}{{\vert Ps \vert}^{2}} Ps & ( 4 )\end{matrix}$$

It is to be noted that “|V|” in the above-described expressions (1), (2), and (4) indicates an absolute value of the vector V, where V is any one of the vectors Pe, Ps, Pes, and Str. In the numerical analysis, the plane indices h, k, l, and m of the hexagonal crystal were varied within a range of 0 to ±9 to perform the vector operations of the above-described expressions (1) to (4).

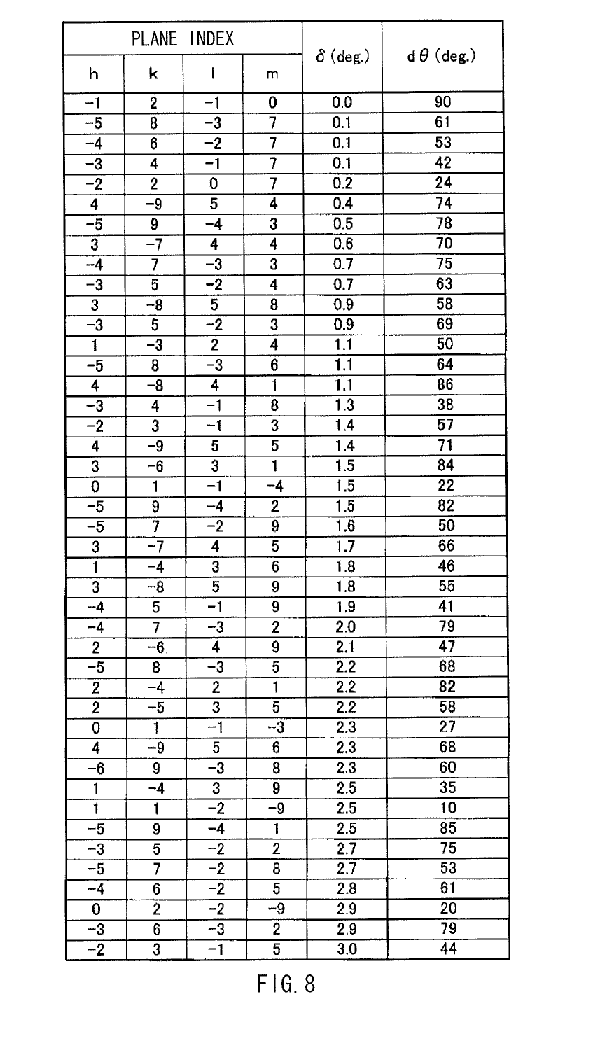

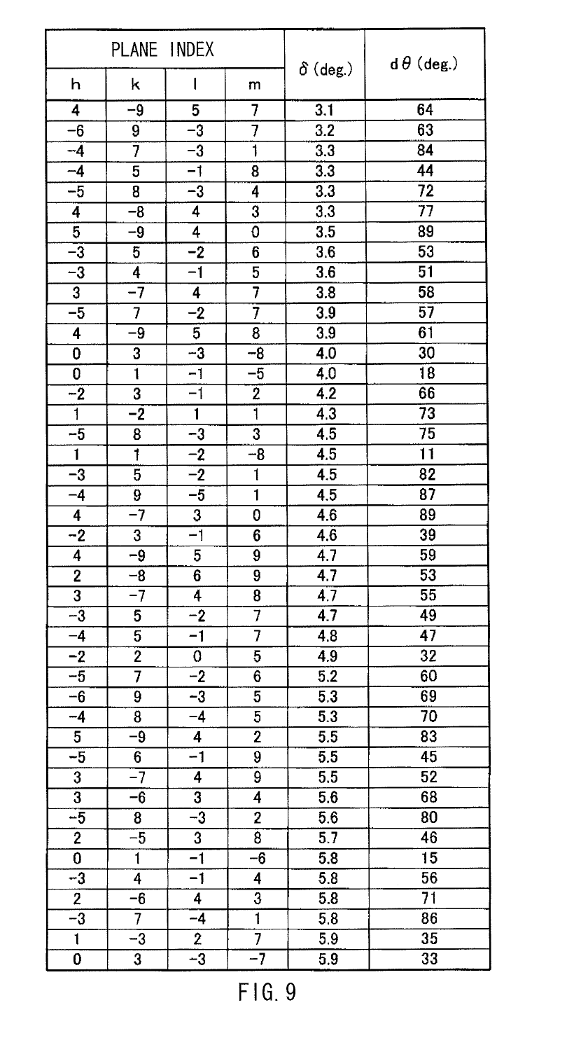

FIGS. 8 and 9 illustrate results of the above-described numerical analysis. FIG. 8 is a table illustrating a relationship between the plane indices of various crystal planes of which a deviation amount δ (=90−α) from the ideal facet of the crystal plane is 3° or less and the deviation amount dθ (the tilt angle) from the c-axis projection direction of the extending direction of the stripe section 101 corresponding to each of the various crystal planes. Moreover, FIG. 9 is a table illustrating a relationship between the plane indices of various crystal planes of which the deviation amount δ from the ideal facet of the crystal plane is within a range from larger than 3° and to smaller than 6° and the deviation amount dθ from the c-axis projection direction of the extending direction of the stripe section 101.

As illustrated in FIGS. 8 and 9, it was found out that, in the hexagonal group III nitride laser diode using the semi-polar base, a large number of crystal planes of which the deviation amount δ from the ideal value (90°) of the angle between the semi-polar plane 1a (the {2, 0, −2, 1} plane) and the resonator facet was smaller than 6° were present. However, by polarization characteristics of laser light in the hexagonal group III nitride laser diode using the semi-polar base, laser characteristics deteriorate with an increase in the deviation amount dθ (the tilt angle) of the extending direction of the stripe section 101 (the propagation direction of laser light). In actuality, it is pointed out in Japanese Unexamined Patent Application Publication (Published Japanese Translation of PCT Application) No. 2010-518626 that, in the case where the semi-polar base is used, optical gain is maximized when the extending direction of the stripe section 101 is oriented along the c axis, and the more the extending direction of the stripe section 101 is deviated from a direction along the c axis, the more optical gain is reduced. Therefore, the deviation amount dθ (the tilt angle) from a c-axis projection direction of the extending direction of the stripe section 101 is preferably as small as possible. A practical range of the deviation amount dθ to obtain favorable optical gain is about 30° or less. It is to be noted that the upper limit of the deviation amount dθ may vary appropriately in consideration of necessary characteristics or the like.

When crystal planes of which the deviation amount δ from the ideal facet of the resonator facet was about 3° or less and of which the deviation amount dθ from the c-axis projection direction of the extending direction of the stripe section 101 was about 30° or less were selected from FIG. 8, the following results in Table 1 were obtained.

TABLE 1

| Plane orientation | | |
|---|---|---|
| {h, k, 1, m} | δ (deg.) | dθ (deg.) |
| {−2, 2, 0, 7} | 0.2 | 24 |
| {0, 1, −1, −4} | 1.5 | 22 |
| {0, 1, −1, −3} | 2.3 | 27 |
| {1, 1, −2, −9} | 2.5 | 10 |
| {0, 2, −2, −9} | 2.9 | 20 |

It was found out from Table 1 that, to maintain the deviation amount δ from the ideal value of the angle α between the plane where the stripe section 101 was formed and the resonator facet at about 3° or less, the extending direction of the stripe section 101 was preferably tilted from the c-axis projection direction at about 10°, 20°, 22°, 24°, or 27°. In particular, when the extending direction of the stripe section 101 was tilted at about 22°, 24°, or 27°, the deviation amount δ from the ideal facet of the resonator facet was allowed to be about 2.3° or less, and the resonator facet was allowed to more closely approach the ideal facet. In other words, it was found out that, when the extending direction of the stripe section 101 was tilted at about 22°, 24°, or 27° from the c-axis projection direction, orthogonality between the extending direction of the stripe section 101 and the resonator facet was further improvable, and favorable laser characteristics were obtainable.

It is to be noted that, in this case, the tilt angle with respect to the c-axis projection direction of the extending direction of the stripe section 101 is preferably determined at 22°, 24°, or 27° with high accuracy. However, when the stripe section 101 is actually fabricated, variations (manufacturing variations) in the tilt angle (dθ) with respect to the c-axis projection direction of the extending direction of the stripe section 101 are caused by a manufacturing error or the like. Therefore, even if the extending direction of the stripe section 101 is deviated from a predetermined direction within a range corresponding to manufacturing variations, such deviation is absorbed by the manufacturing error, and does not cause a practical issue. Therefore, when manufacturing variations in the extending direction of the stripe section 101 were closely studied, it was found out that manufacturing variations within a range of about ±0.5° occurred. In other words, it was found out that the tilt angle (dθ) with respect to the c-axis projection direction of the extending direction of the stripe section 101 may be and allowed to be deviated by about ±0.5° from 22°, 24°, or 27°.

In the above-described numerical analysis, the deviation amount δ from the ideal value (90°) of the angle α between the plane where the stripe section 101 was formed and the resonator facet, that is, a deviation amount of the angle α between the plane where the stripe section 101 was formed and the resonator facet in the thickness direction of the semiconductor base 1 was analyzed. However, to verify the orthogonality between the extending direction of the stripe section 101 and the resonator facet, it is also necessary to consider a deviation amount (a horizontal deviation amount) between the extending direction of the stripe section 101 and the resonator facet in the plane where the stripe section 101 is formed.

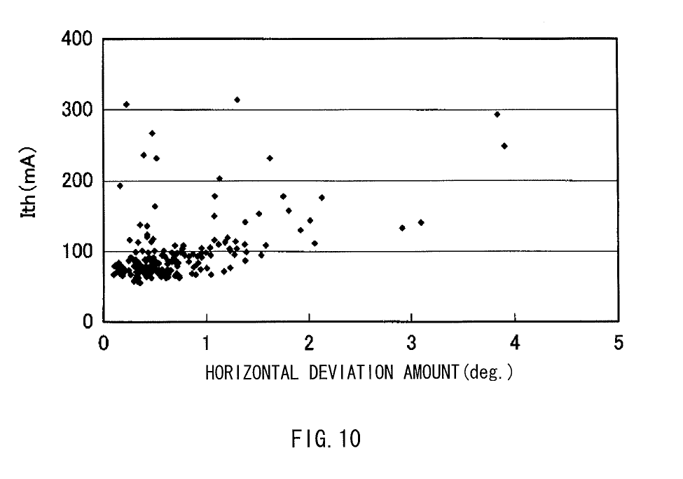

FIG. 10 illustrates a relationship between the horizontal deviation amount of the angle between the extending direction of the stripe section 101 and the resonator facet in the plane where the stripe section 101 was formed and the lasing threshold current Ith (experimental results). A horizontal axis in characteristics illustrated in FIG. 10 represents the horizontal deviation amount from (an tilt angle: an absolute value) from the ideal value (90°) of the extending direction of the stripe section 101 with respect to the resonator facet in the plane where the stripe section 101 was formed, and a vertical axis represents the lasing threshold current Ith.

As illustrated in FIG. 10, it was found out that, when the horizontal deviation amount from the ideal value (90°) of the extending direction of the stripe section 101 with respect to the resonator facet in the plane where the stripe section 101 was formed was within a range of about ±2°, a distribution of the lasing threshold current Ith was not largely deteriorated, and a favorable value was obtained.

It was found out from the results of the above-described numerical analysis (refer to Table 1) and the experimental results (refer to FIG. 10) that, when the extending direction of the stripe section 101 was tilted at an angle ranging from about 8° to about 12° or from about 18° to about 29° both inclusive with respect to the c-axis projection direction, superior laser characteristics were obtained.

It is to be noted that the present disclosure is allowed to have the following configurations.

(1) A laser diode including:

a semiconductor base made of a hexagonal Group III nitride semiconductor and having a semi-polar plane oriented along a {2, 0, −2, 1} direction;

an epitaxial layer including a light-emitting layer forming an optical waveguide of laser light, and formed on the semi-polar plane of the semiconductor base, the epitaxial layer allowing a propagation direction of the laser light to be tilted, in an optical waveguide plane, at an angle ranging from about 8° to about 12° or about 18° to about 29° both inclusive with respect to a direction of projection of a c axis onto the optical waveguide plane, the optical waveguide plane including the propagation direction of the laser light and being parallel to the semi-polar plane;

two resonator facets disposed at both ends of the optical waveguide of the laser light;

a first electrode formed on the epitaxial layer; and

a second electrode formed on a plane opposite to the semi-polar plane where the epitaxial layer is formed of the semiconductor base.

(2) The laser diode according to (1), in which the propagation direction of the laser light is tilted at an angle ranging from about 22° to about 27° both inclusive with respect to the direction of projection of the c axis onto the optical waveguide plane.

(3) The laser diode according to (2), in which the propagation direction of the laser light is tilted at any one of about 22°, about 24°, and about 27° with respect to the direction of projection of the c axis onto the optical waveguide plane.

(4) The laser diode according to any one of (1) to (3), in which a deviation amount from 90° of an angle between the resonator facet and the semi-polar plane is about 3° or less.

(5) The laser diode according to any one of (1) to (4), wherein the epitaxial layer includes, in a surface thereof which faces the first electrode, a ridge section extending along the propagation direction of the laser light.

(6) A method of manufacturing a laser diode, the method including:

forming an epitaxial layer on a semi-polar plane oriented along a {2, 0, −2, 1} direction of a semiconductor base made of a hexagonal Group III nitride semiconductor, the epitaxial layer including a light-emitting layer forming an optical waveguide of laser light, and allowing a propagation direction of the laser light to be tilted, in an optical waveguide plane, at an angle ranging from about 8° to about 12° or about 18° to about 29° both inclusive with respect to a direction of projection of a c axis onto the optical waveguide plane, the optical waveguide plane including the propagation direction of the laser light and being parallel to the semi-polar plane;

forming a first electrode and a second electrode on the epitaxial layer and a plane opposite to the semi-polar plane of the semiconductor base, respectively; and

forming two resonator facets at both ends of the optical waveguide of the laser light.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A laser diode comprising:
a semiconductor base made of a hexagonal Group III nitride semiconductor and having a semi-polar plane oriented along a {2, 0, −2, 1} direction;
an epitaxial layer including a light-emitting layer forming an optical waveguide of laser light, and formed on the semi-polar plane of the semiconductor base, the epitaxial layer allowing a propagation direction of the laser light to be tilted, in an optical waveguide plane, at an angle ranging from about 8° to about 12° or about 18° to about 29° both inclusive with respect to a direction of projection of a c axis onto the optical waveguide plane, the optical waveguide plane including the propagation direction of the laser light and being parallel to the semi-polar plane;
two resonator facets disposed at both ends of the optical waveguide of the laser light;
a first electrode formed on the epitaxial layer; and
a second electrode formed on a plane opposite to the semi-polar plane where the epitaxial layer is formed of the semiconductor base.

2. The laser diode according to claim 1, wherein the propagation direction of the laser light is tilted at an angle ranging from about 22° to about 27° both inclusive with respect to the direction of projection of the c axis onto the optical waveguide plane.

3. The laser diode according to claim 2, wherein the propagation direction of the laser light is tilted at any one of about 22°, about 24°, and about 27° with respect to the direction of projection of the c axis onto the optical waveguide plane.

4. The laser diode according to claim 1, wherein a deviation amount from 90° of an angle between the resonator facet and the semi-polar plane is about 3° or less.

5. The laser diode according to claim 1, wherein the epitaxial layer includes, in a surface thereof which faces the first electrode, a ridge section extending along the propagation direction of the laser light.

6. A method of manufacturing a laser diode, the method comprising:
forming an epitaxial layer on a semi-polar plane oriented along a {2, 0, −2, 1} direction of a semiconductor base made of a hexagonal Group III nitride semiconductor, the epitaxial layer including a light-emitting layer forming an optical waveguide of laser light, and allowing a propagation direction of the laser light to be tilted, in an optical waveguide plane, at an angle ranging from about 8° to about 12° or about 18° to about 29° both inclusive with respect to a direction of projection of a c axis onto the optical waveguide plane, the optical waveguide plane including the propagation direction of the laser light and being parallel to the semi-polar plane;
forming a first electrode and a second electrode on the epitaxial layer and a plane opposite to the semi-polar plane of the semiconductor base, respectively; and
forming two resonator facets at both ends of the optical waveguide of the laser light.
